(19) United States
(12) Patent Application Publication
(10) Pub. No.: US 2005/0269201 A1
(43) Pub. Date: Dec. 8, 2005

(54) Methods of forming PVD target/backing plate constructions

(75) Inventors: Brett M. Clark, Spokane, WA (US); Wuwen Yi, Veradale, WA (US); Roberta L. Smits, Post Falls, ID (US); Alan L. Brown, Post Falls, ID (US)

Correspondence Address: WELLS ST. JOHN P.S., 601 W. FIRST AVENUE, SUITE 1300, SPOKANE, WA, 99201, US

(73) Assignee: Honeywell International Inc.

(21) Appl. No.: 11/186,213

(22) Filed: Jul. 21, 2005

Related U.S. Application Data
(63) Continuation-in-part of application No. PCT/US04/08343, filed on Mar. 17, 2004.
(60) Provisional application No. 60/460,151, filed on Apr. 2, 2003.

(51) Int. Cl. C23C 14/32

(52) U.S. Cl. 204/192.13; 204/192.12

(57) ABSTRACT

The invention encompasses a construction in which a PVD target is bonded to a backing plate. The target has a bonding surface utilized in forming the bond to the backing plate, and the backing plate has a bonding surface utilized in forming the bond to the target. One or more holes extend into the target through the target bonding surface and/or one or more holes extend into the backing through the backing plate bonding surface. The invention also includes methods of forming PVD target/backing plate constructions, and methods of utilizing holes extending into one or both of the target and the backing plate of the target/backing plate construction during ultrasound determination of a thickness of the target.

### RELATED PATENT DATA

This patent resulted from a continuation-in-part application of PCT/US2004/008343 which was filed Mar. 17, 2004, and is incorporated by reference herein; and which claims priority to U.S. Provisional Patent Application Ser. No. 60/460,151, which was filed Apr. 2, 2003, and is incorporated by reference herein.

### TECHNICAL FIELD

The invention pertains to physical vapor deposition (PVD) target/backing plate constructions, and to methods of forming such constructions.

### BACKGROUND OF THE INVENTION

Physical vapor deposition is commonly utilized for forming thin layers of material across semiconductor substrates. FIG. 1 diagrammatically illustrates a PVD process. A target/backing plate construction 10 is provided proximate a substrate 12 (such as, for example, a semiconductor substrate) within an appropriate apparatus (not shown).

Construction 10 comprises a PVD target 14 and a backing plate 16. The assembly is shown comprising an ENDURA™ configuration, such as is available from Honeywell International Inc. Backing plate 16 has a configuration suitable for retaining construction 10 within the sputtering apparatus. Target 14 can comprise any suitable composition, and in the shown application comprises a conductive material.

Target 14 is shown directly bonded to backing plate 16 (i.e., physically against the backing plate). Accordingly, target 14 has a bonding surface 19 directly against a bonding surface 17 of the backing plate 16. The bond between the target and backing plate can be formed by, for example, a diffusion bonding process.

An exposed surface 18 of target 14 can be referred to as a sputtering surface. High energy particles are impacted against surface 18 to cause material to be released from surface 18. The released material is diagrammatically illustrated by arrows 20. The released material forms a film 22 across an upper surface of substrate 12.

The surfaces 18 and 19 of the target can be referred to as opposing primary surfaces. The surfaces are referred to as “primary” surfaces to indicate that the surfaces have more area than other surfaces of the target (such as the sidewall surfaces), and are thus major surfaces of the target.

Although target 14 is shown comprising a conductive material, it is to be understood that the target can comprise any suitable construction for forming a desired film, and accordingly can also comprise non-conductive materials, such as, for example, ceramic materials.

The removal of material from target 14 reduces a thickness of the target. Eventually, the target is eroded to an extent that the target is no longer suitable for utilization in a PVD operation. The duration of time that a target can be utilized in PVD operations before the target is eroded to the point that it is no longer useful can be referred to as a lifetime of the target.

FIGS. 2 and 3 illustrate target/backing plate construction 10 after the sputtering surface 18 of target 14 has been eroded through utilization in PVD processes. It is noted that the erosion is generally not uniform across the sputtering surface, but rather sputtering tracks 30 and 32 form at regions of target 14 where erosion is most severe.

A tradeoff occurs in utilizing target/backing plate constructions during sputtering operations in attempting to obtain a maximal lifetime from a target, while also avoiding having the sputtering tracks 30 or 32 extending through the target and into the backing plate (i.e., punching through the interface of the target surface 19 and the backing plate surface 17). If the sputtering tracks penetrate entirely through the target during a PVD operation, material from the backing plate can be sputtered which can adversely impact a film deposited from construction 10.

FIG. 4 illustrates target/backing plate construction 10 prior to utilization of the construction in a PVD operation. Accordingly, no erosion of surface 18 has occurred. It is desired to accurately determine the thickness of target 14 (i.e., to accurately determine the thickness between sputtered surface 18 and bonding surface 19) so that the remaining lifetime of the target can be estimated as the target is eroded by simply measuring the remaining thickness of the target and comparing the remaining thickness to the starting thickness.

Target 14 has sidewalls 40 extending between bonding surface 19 and sputtering surface 18. The thickness of target 14 along the edges can be measured as a length of sidewalls 40 if the entirety of the sidewalls is exposed. However, target 14 is inset within backing plate 16 so that only a portion of the sidewall surfaces 40 is exposed for measurement. Further, even if the sidewalls are exposed, the thickness of the target at the edges only accurately reflects the thickness of the target at interior regions if the target thickness is uniform across the interior regions and the edges. Rather than assuming the target thickness to be uniform across the interior regions and edges, it is frequently desired to confirm the uniformity of the target thickness during the determination of the target thickness.

The desire to accurately measure target thickness and to confirm the uniformity of target thickness across edge and interior regions has lead to development of ultrasound methods for determining the thickness of target 14. An ultrasound transducer 42 is shown in FIG. 4, and is shown over sputtering surface 18. Ultrasound transducer 42 is linked to a processor 44, and utilized to send and receive ultrasound radiation 46. The ultrasound radiation (also referred to as acoustic radiation) is directed toward sputtering surface 18. Ultrasound radiation can reflected back to transducer 42 from any surface orthogonal to the direction of travel of the ultrasound waves, provided that the surface occurs at an interface between two materials having different acoustic impedance relative to one another. Acoustic impedance is generally related to the physical density of a material. Accordingly if the two materials of an interface have different densities relative to one another, ultrasound radiation will be reflected from the interface.

Each interface within the target can reflect a fraction of the ultrasound radiation impacting it while transmitting the remaining fraction of ultrasound radiation. The relative amount of radiation reflected, versus the amount transmitted for a given interface can, for the reasons discussed above, depend on the difference in compositions of the materials joining at the interface. If the materials have different compositions that in turn lead to significant differences in acoustic impedance, a large reflection will occur; and if the materials are about the same in acoustic impedance, very little, if any, reflection will occur.

For the shown construction 10, ultrasound reflections are expected from surface 18; from the interface between surface 19 of target 14 and surface 17 of backing plate 16; and from a back surface 50 of backing plate 16.

Ultrasound techniques work well when the target is very different in composition from the backing plate 16 of FIG. 4. However, if the target has a similar composition to the backing plate, there will be little to no acoustic reflection from the interface of the target and backing plate.

FIG. 5 diagrammatically shows a graph of ultrasound signals expected from construction 10 utilizing transducer 42 when materials 14 and 16 have compositions significantly different from one another. A first peak 51 results from a reflection from surface 18 (the so-called front surface of construction 10 in the shown orientation of FIG. 4 in which transducer 42 is above surface 18), a second peak 52 occurs from a reflection off the interface of surfaces 17 and 19, and a third peak 54 occurs from reflections off from the so-called back surface 50 of construction 10. If materials 14 and 16 were similar to one another, peak 52 would be very small, and in some instances would be undetectable.

The signals shown in FIG. 5 are for diagrammatic purposes only. The graph is not quantitatively accurate, but instead is provided to aid in a general understanding of how ultrasound reflections can be utilized to estimate a thickness of target 14.

The time between peaks 51 and 52 is directly related to the thickness of target 14, and the relationship between the time and the thickness can be readily determined by persons of ordinary skill in the art. A problem which can occur, as discussed above, is that if materials 14 and 16 are very similar in acoustic amplitude relative to one another, peak 52 can be essentially undetectable. Thus, the ultrasound methodology for determining target thickness can fail in applications in which the target and backing plate of construction 10 have similar acoustic impedance relative to one another. Unfortunately, many common applications comprise targets and backing plates having similar acoustic impedances relative to one another. For instance, it is common for the target and backing plate to both predominately comprise the same material. In particular applications, the target and backing plate can both comprise relatively high purity compositions of the same element. For example, the target and backing plate can both comprise high purity aluminum or high purity copper. The term “high purity” refers to any composition having a purity of greater than 99 atomic %. In many applications, if the target and backing plate both predominately comprise the same element (with the term “predominately comprise” indicating that a material comprises more than 50 atomic % of the element) the acoustic impedance of the target and backing plate can be too similar to one another to allow the process of FIGS. 4 and 5 to be utilized for determining target thickness.

Ultrasound technology has many advantages for determining target thickness. Among them, ultrasound technology can be relatively quick and convenient. Accordingly, it would be desirable to develop methods by which ultrasound technology can be utilized for determining target thicknesses in constructions in which a target and a backing plate have similar acoustic impedances to one another.

### SUMMARY OF THE INVENTION

In one aspect, the invention pertains to a method of forming a PVD target/backing plate construction. A PVD target is provided. The target has a pair of opposing primary surfaces, with one of the primary surfaces being a sputtering surface and the other of the primary surfaces being a bonding surface. A backing plate is provided, and the backing plate has a bonding surface. A hole is extended into the target through the target bonding surface. The target is bonded to the backing plate. After the target is bonded to the backing plate, the hole is utilized to estimate a thickness of the target.

In one aspect, the invention encompasses a method of forming a PVD target/backing plate construction in which at least one hole is formed to extend into a backing plate through a backing plate bonding surface. The backing plate is then bonded to a PVD target, and the hole is utilized to estimate a thickness of the target.

In one aspect, the invention encompasses PVD target/backing plate constructions having one or more holes extending into a backing plate through a backing plate bonding surface and/or having holes extending into a target through a bonding surface of the target. The holes can have any suitable size. In a particular aspect, the holes can have a depth of from about 0.005 inch to about 0.1 inch, and can have a maximum width of from about 0.005 inch to about 0.1 inch.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Preferred embodiments of the invention are described below with reference to the following accompanying drawings.

FIG. 1 is a diagrammatic, cross-sectional view of a PVD deposition process, and shows a PVD target/backing plate construction proximate a substrate.

FIGS. 2 and 3 are a diagrammatic, cross-sectional side view and diagrammatic top view, respectively, of a prior art PVD target/backing plate construction illustrating an erosion profile of a sputtering surface of the target.

FIG. 4 is a diagrammatic, cross-sectional side view of a prior art PVD/target construction and an ultrasound apparatus utilized to estimate a thickness of the target component of the construction.

FIG. 5 is a graph of amplitude vs. time diagrammatically illustrating ultrasound signals obtained during ultrasound estimation of the target thickness of the FIG. 4 target/backing plate construction.

FIG. 6 is a diagrammatic, cross-sectional view of a target formed in accordance with an exemplary method of the present invention.

FIG. 7 is a diagrammatic, cross-sectional side view of a target/backing plate construction incorporating the target of FIG. 6.

FIG. 8 is a diagrammatic, cross-sectional side view of the target/backing plate construction of FIG. 7 subjected to an ultrasound determination of the thickness of the target.

FIG. 9 is a graph of amplitude vs. time diagrammatically illustrating signals expected from the ultrasound methodology of FIG. 8.

FIG. 10 is a diagrammatic, cross-sectional side view of the FIG. 6 target shown at a processing stage subsequent to that of FIG. 6 in accordance with a second embodiment of the invention.

FIG. 11 is a diagrammatic, cross-sectional side view of a target/backing plate construction incorporating the FIG. 10 target.

FIG. 12 is a top view of the FIG. 6 target illustrating an exemplary pattern of holes which can be formed in the target.

FIG. 13 is a diagrammatic, cross-sectional side view of a backing plate formed in accordance with a third embodiment of the invention.

FIG. 14 is a diagrammatic, cross-sectional side view of a physical vapor deposition target/backing plate construction incorporating the backing plate of FIG. 13.

FIG. 15 is a graph of amplitude vs. time diagrammatically illustrating an exemplary pattern of signals expected from ultrasound determination of the thickness of the target of the FIG. 14 construction.

FIG. 16 is a color graph showing experimental data obtained from an ultrasound analysis of a physical vapor deposition target/backing plate construction formed in accordance with methodology of the present invention. The target was 99.9999 atomic % copper, and the backing plate was copper having approximately 1.2 atomic % chromium therein.

### DETAILED DESCRIPTION OF THE PREFERRED EMBODIMENTS

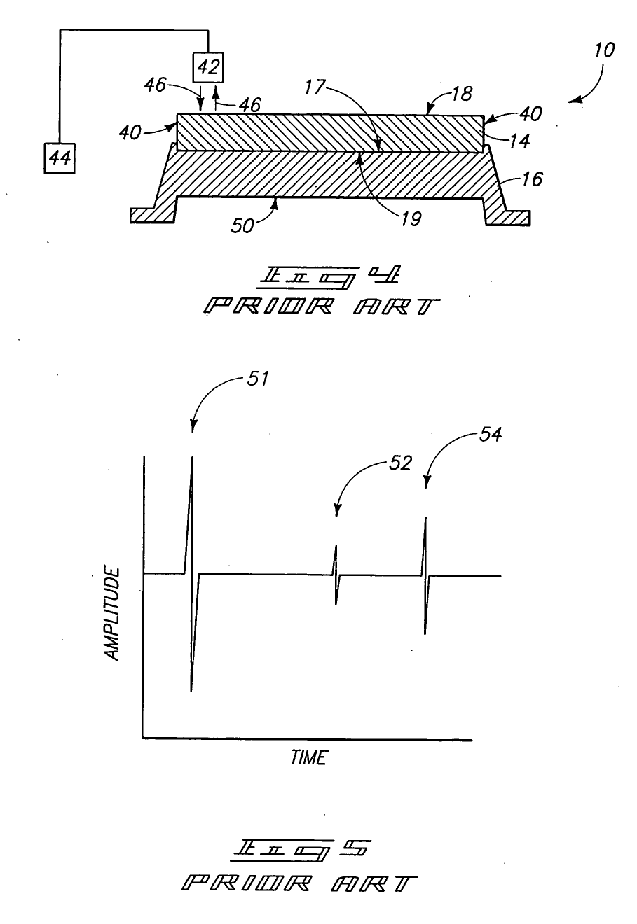

One aspect of the invention is to develop methodology for overcoming the problem described above with reference to prior art FIGS. 4 and 5 of it being difficult to measure a target thickness through ultrasound methods when the target and the backing plate of a target/backing plate construction both have similar acoustic impedances. In particular aspects, the invention encompasses providing regions of altered acoustic impedance within a target and proximate a bonding surface of the target in a target/backing plate construction; in additional or alternative aspects, the invention encompasses forming regions of altered acoustic impedance within a backing plate and proximate a bonding surface of the backing plate in the target/backing plate construction.

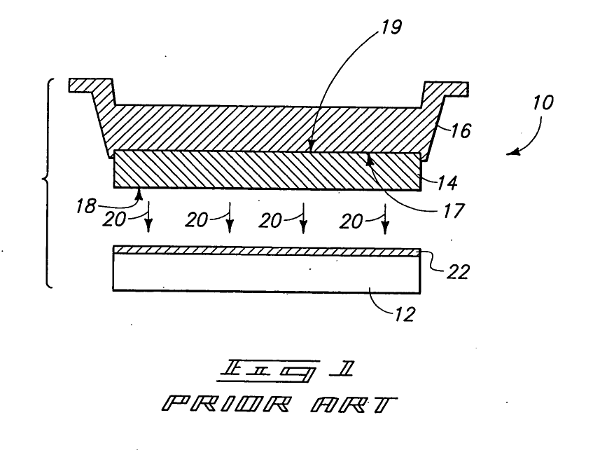

An exemplary method of forming altered acoustic impedance regions within a target is described with reference to FIGS. 6-9. Similar numbering will be used to describe FIGS. 6-9 as was used above in describing prior art FIGS. 1-5, where appropriate. Referring to FIG. 6, a target 14 is provided. The target comprises a sputtering surface 18 and a bonding surface 19. Openings 100 are formed to extend through bonding surface 19 and into target 14.

Openings 100 can have any suitable shape and depth. It can be preferred, however, that the openings be relatively small so that the openings do not interfere with subsequent bonding of the target in a target/backing plate construction. Exemplary openings will have an approximately circular lateral periphery and a diameter “D” extending across the periphery. The diameter corresponds to a maximum width of the openings, and can be, for example, from about 5 thousandths of an inch to about 100 thousandths of an inch. The openings have a depth “X”, and such can be, for example, from about 5 thousandths of an inch to about 100 thousandths of an inch. In a particular aspect, the openings are formed to have a diameter of 0.050 inch, and a depth of 0.030 inch. All of the openings can be formed with identical widths and depths relative to one another, or can be formed with different widths and depths.

The openings have a bottom periphery 102, and such is preferably substantially planar, and also substantially parallel to sputtering surface 18. Accordingly, ultrasound waves which are orthogonal to sputtering surface 18 will also be orthogonal to surface 102 so that strong reflections of ultrasound waves can be obtained from both surface 18 and surface 102 using the same ultrasound transducer.

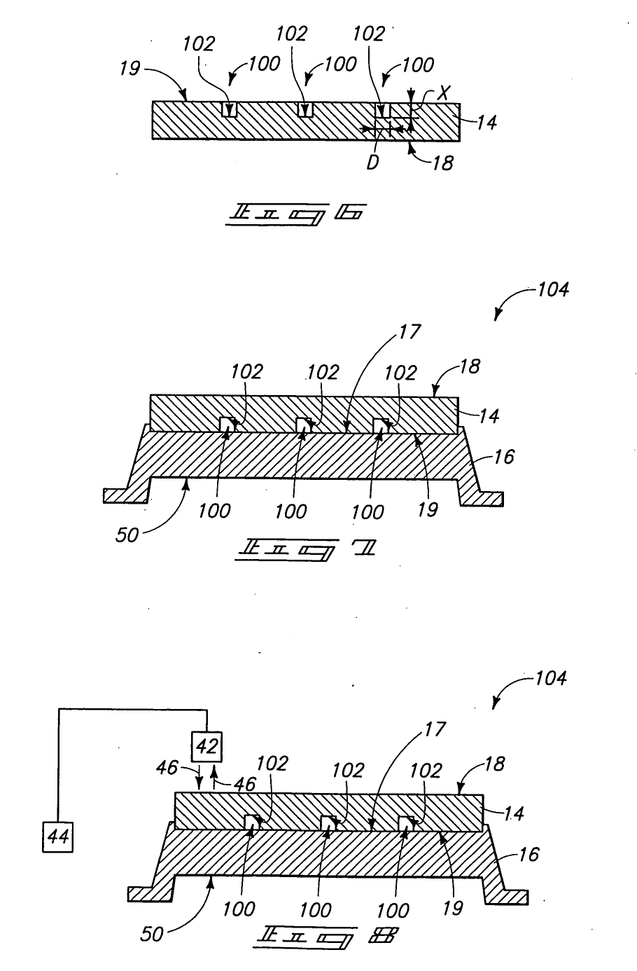

Referring next to FIG. 7, target 14 is inverted and bonded to a backing plate 16 to form a target/backing plate construction 104. In the shown construction, bonding surface 19 of target 14 is bonded directly to a bonding surface 17 of backing plate 16. Such can be accomplished by, for example, forming a diffusion bond between the target and the backing plate. It is to be understood that the invention encompasses other aspects (not shown) wherein surfaces 17 and 19 are proximate one another, but not directly bonded to one another. In such other aspects, a solder or other material can be utilized to retain the target 14 to the backing plate 16.

Backing plate 16 comprises the back surface 50 described previously with reference to FIG. 4, and target 14 comprises the sputtering surface 18 described previously with reference to FIG. 4.

Referring to FIG. 8, an ultrasound transducer 42 is provided over sputtering surface 18. Transducer 42 is connected to a control unit 44 as described previously with reference to FIG. 4, and utilized to send and receive ultrasound waves 46.

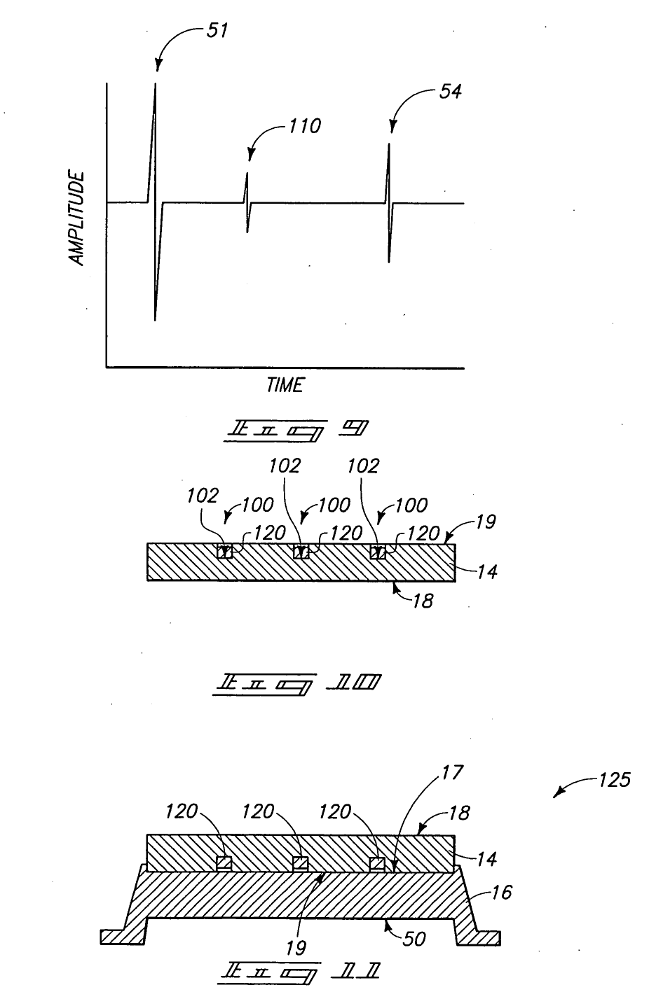

FIG. 9 shows a graph of amplitude vs. time for ultrasound reflections obtained from construction 104 utilizing the transducer 42. The graph of FIG. 9 shows the front surface reflection 51 and back surface reflection 54 described previously with reference to FIG. 5. The graph of FIG. 9 is illustrating reflections obtained when ultrasound radiation passes through target 14 along an axis penetrating to one of the openings 100. Accordingly, the graph shows a reflection 110 corresponding to an interface of hole periphery 102 and hole 100. There may also be a reflection from the acoustic radiation passing through the interface of the hole 100 and backing plate 16, but such would typically be very small, and essentially non-existent, and such reflection is therefore not shown in FIG. 9.

A thickness of target 14 can be determined from the time delay between reflection 51 and reflection 110. Specifically, the time between reflection 51 and 110 can be related to a distance between sputtering surface 18 and peripheral surface 102 of opening 100. If the depth of opening 100 is known, then such can be added to the distance between sputtering surface 18 and surface 102 to determine a total thickness of target 14 at the location of an opening.

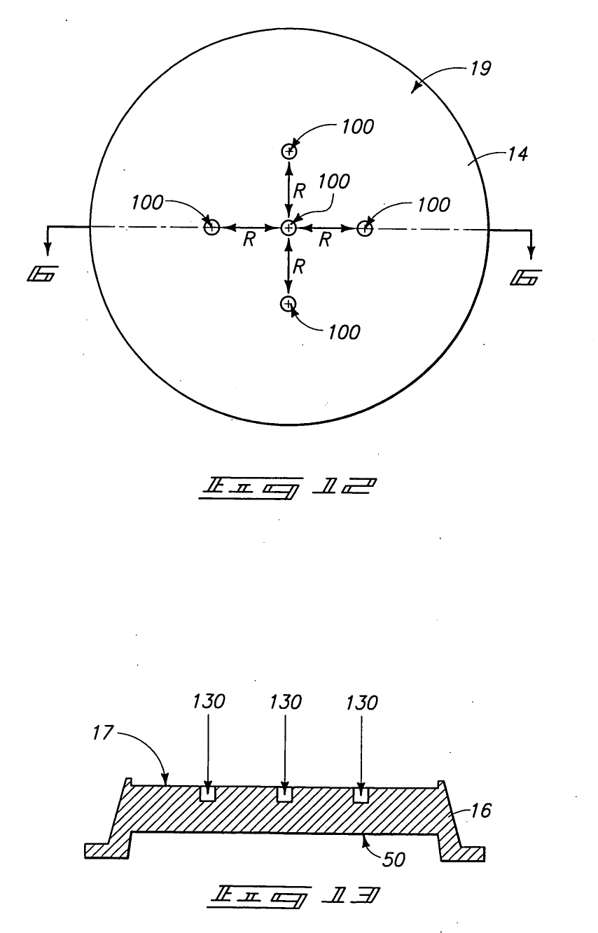

Openings 100 are left unfilled in construction 104 of the embodiment of FIGS. 7 and 8. In other words, openings 100 are empty except for gas. FIGS. 10 and 11 illustrate an alternative embodiment wherein the openings are at least partially filled with a non-gaseous material. Referring initially to FIG. 10, such illustrates target 14 at a processing stage subsequent to that of FIG. 6. Openings 100 are partially filled with a material 120. The shown material is a solid conductive material, but it is to be understood that other materials can be utilized, such as, for example, semi-solid materials, and insulative materials, including, for example, ceramics.

It can be preferred that material 120 have a substantially different acoustic impedance than the material of target 14 so that a strong acoustic reflection can be obtained from the interface of material 120 and a material of target 14 at surface 102 of the openings. It can also be preferred that material 120 have a coefficient of thermal expansion approximately equal to that of the material of target 14 so that the target material is not cracked during heating of the target material that can occur during bonding of the target to a backing plate and/or during utilization of the target in a physical vapor deposition apparatus. However, if material 120 comprises a different coefficient of thermal expansion than target 14, problems associated with the different rates of expansion of material 120 and target 14 can be alleviated by only partially filling the openings 100 with material 120.

Referring to FIG. 11, the target of FIG. 10 is shown bonded to a backing plate 16 to form a target/backing plate construction 125. A thickness of target 14 of construction 125 can be determined using ultrasound methodology similar to that described above with reference to FIGS. 8 and 9:

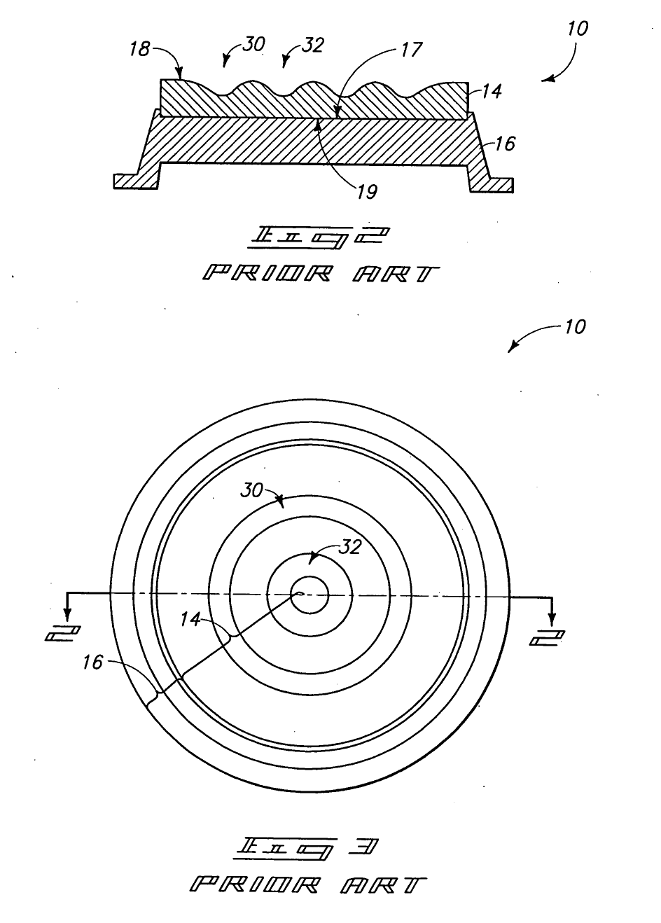

The various openings described in the constructions of FIGS. 6-8, 10 and 11 can be formed in any desired pattern within target 14. It can be preferred, however, that the majority of the openings are provided at a location directly beneath a region where the target is expected to be most deeply eroded during a physical vapor deposition process. As was described previously with reference to FIGS. 2 and 3, a sputtering target will typically have an erosion profile formed across its sputtering surface as the target is utilized for physical vapor deposition. There will be particular regions (typically referred to as sputter tracks) which are more deeply eroded within the target surface than other regions. It can be particularly desired to know the thickness of the target relative to the regions where sputter tracks are expected to occur, as such are the regions which are most likely to be punched through during utilization of the target in physical vapor deposition processes if the processes are conducted for a time longer than the practical usable lifetime of the target.

FIG. 12 shows a top view of the target 14 of FIG. 6, and shows holes 100 arranged in a pattern such that there is a center hole and four holes radially outward of the center hole. The four radially outward holes are equidistant of one another, and separated from the center hole by the same radial distance “R”. Preferably, the four radially outward holes are at a radial location of a deepest expected portion of a sputter track which is expected to form when target 14 is utilized in a physical vapor deposition process. The utilization of multiple holes can provide information on the uniformity of thickness of target 14, as well as providing information on the thickness of target 14 in local areas.

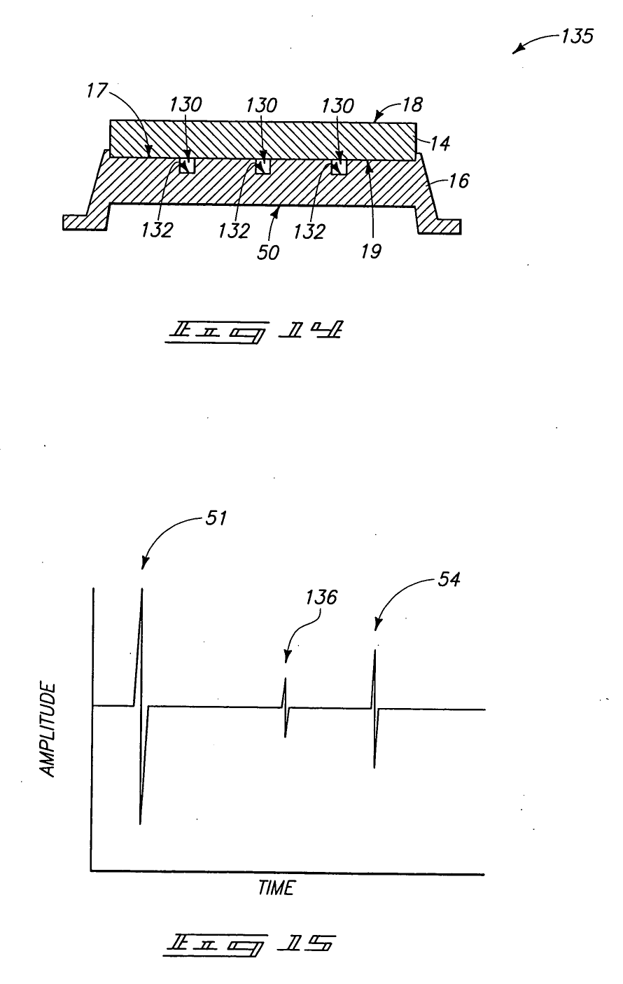

Although the embodiments described above comprise holes formed in a target of a target/backing plate construction, it is to be understood that the holes can alternatively, or additionally, be formed in a backing plate of the construction. Such aspect of the invention is described with reference to FIGS. 13-15. Referring initially to FIG. 13, a backing plate 16 is illustrated having holes 130 extending through a bonding surface 17 of the backing plate and into the material of the backing plate. Holes 130 can comprise any suitable dimension, and in particular aspects will comprise the preferred dimensions described above with reference to the holes 100 of FIG. 6. It can be preferred that holes 130 be relatively small, so that the holes do not interfere with bonding between backing plate 16 and a target.

FIG. 14 shows a target/backing plate construction 135 comprising the backing plate 16 of FIG. 10.

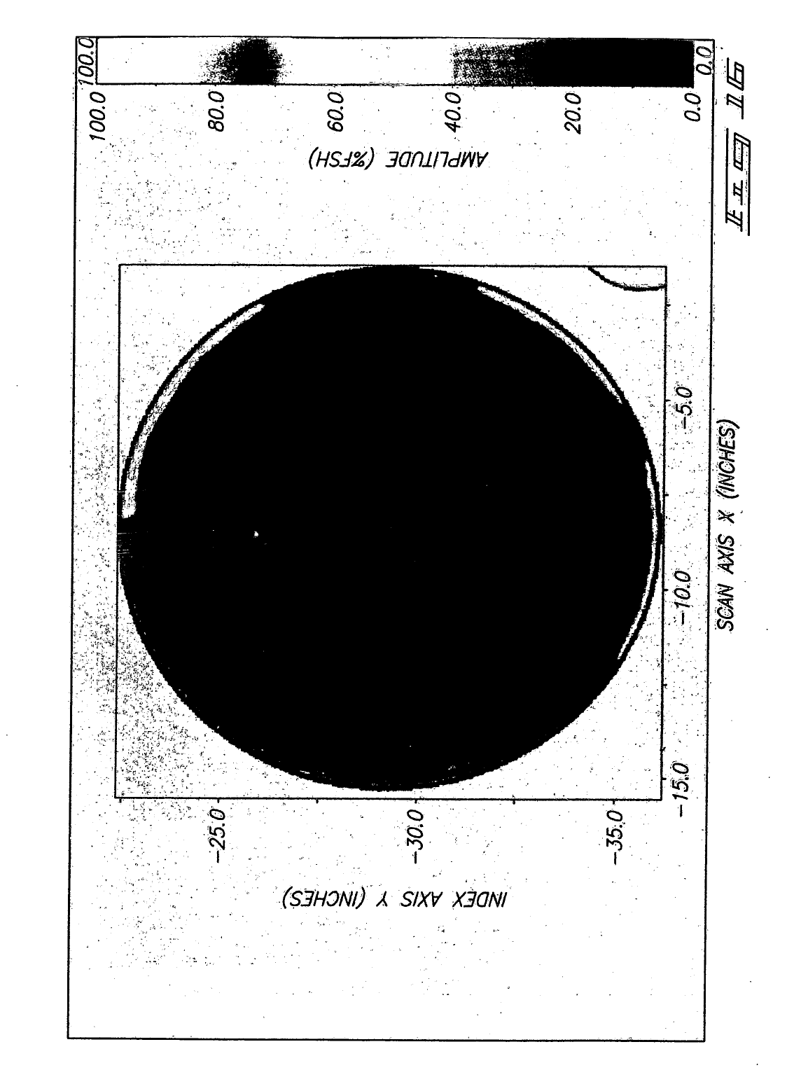

A thickness of target 14 of construction 135 can be estimated by providing an ultrasound transducer over sputtering surface 18 (similar to the process described above with reference to FIG. 8), and determining the time between reflections received by the ultrasound transducer. Openings 130 have a top surface defined by bonding surface 19 of target 14, and a bottom surface 132. FIG. 15 is a graph of amplitude vs. time for ultrasound reflections expected from construction 135 as ultrasound radiation is passed through surface 18 and reflections from construction 135 are received by a transducer over surface 18. The graph of FIG. 15 represents information obtained when an ultrasound radiation is passed along an axis extending through one of the openings 130. The graph comprises a first reflection 51 corresponding to a reflection off of surface 18, and comprises a last reflection 54 corresponding to a reflection from back surface 50. The graph also comprises a second reflection 136 corresponding to the reflection from the interface of surface 19 of target 14 and a hole 130. A thickness of target 14 can be determined from the spacing of reflections 51 and 136.

Although the embodiments described above with reference to FIGS. 8, 9 and 15 refer to the positioning of an ultrasound transducer above the surface 18 of a target/backing plate construction, it is to be understood that the transducer could alternatively be provided proximate back surface 50.

Openings 130 can be left empty of solid material (as shown), or alternatively can be at least partially filled with solid materials similar to the embodiment described above with reference to FIGS. 10 and 11.

The invention has been tested utilizing a target/backing plate construction in which the target is copper of about 99.9999 atomic % purity and the backing plate is copper with about 1.2 atomic % chromium. Typically, it would be difficult, and frequently impossible, to locate an interface between such target and backing plate utilizing prior art methods. However, methodology of the present invention readily detected holes formed in the backing plate. Such is illustrated in FIG. 16, where five holes can be readily distinguished as lighter regions on the darker background.

Methodology of the present invention can be utilized in any application in which a bond between a target and backing plate will be difficult to detect by prior art methods, including applications in which the target and backing plate predominately comprise the same material as one another, or otherwise have substantially the same acoustic impedance as one another (with the term substantially the same acoustic impedance referring to an acoustic impedance which differs by less than 5%). Also, although the invention is described with reference to targets bonded directly to backing plates, it is to be understood that the invention can also be utilized in applications in which the target is bonded to the backing plate through an intervening material, such as, for example, a solder. The invention can be particularly advantageous relative to prior art processes if the intervening material has an acoustic impedance substantially the same as the target and backing plate.

In applications in which the target is directly bonded to the backing plate, the bonding methods can be conventional methods including, for example, hot isostatic pressing at high temperature and pressure to achieve diffusion bonding.

The holes utilized in methodology of the present invention preferably are small enough to have little to no effect on bonding between a target and backing plate, and also preferably would have little or no effect on electrical or thermal conduction between the target and backing plate.

1. A method of forming a physical vapor deposition target/backing plate construction, comprising:
providing a physical vapor deposition target, the target having a pair of opposing primary surfaces, one of the primary surfaces being a sputtering surface and the other of the primary surfaces being a bonding surface;
providing a backing plate having a bonding surface and a back surface in opposing relation to the bonding surface;
forming a hole extending into the target through the target bonding surface;
providing the target bonding surface proximate the backing plate bonding surface and bonding the target to the backing plate;
sputter-depositing material from the target onto a substrate; and
after the bonding and before the sputter-depositing, utilizing the hole to estimate a thickness of the target by ascertaining a time delay between ultrasound reflections from a surface of the hole and ultrasound reflections from one or more of the bonding surface of the target, the sputtering surface of the target, the bonding surface of the backing plate and the back surface of the backing plate.

2. The method of claim 1 wherein the target and backing plate are approximately the same in composition relative to one another.

3. The method of claim 1 wherein the bonding of the target to the backing plate comprises bonding the target to be physically against the backing plate.

4. The method of claim 1 wherein the target and backing plate are approximately the same in acoustic impedance relative to one another.

5. The method of claim 1 further comprising, prior to the bonding, at least partially filling the hole with a material; and wherein the utilization of the hole to estimate the thickness of the target comprises ascertaining a time delay between ultrasound reflections from a surface of the material in the hole and ultrasound reflections from the sputtering surface of the target.

6. The method of claim 1 wherein:
multiple holes are formed to extend through the target bonding surface and into the target; and
the multiple holes are utilized to estimate the thickness of the target and the uniformity of the target thickness.

7. The method of claim 6 further comprising providing an expected sputtering profile of the sputtering surface of the target during utilization of the target for physical vapor deposition; wherein the expected sputtering profile comprises one or more regions where the target is expected to be most deeply eroded during physical vapor deposition, and wherein at least one of the holes is provided at a location corresponding to one of the regions where the target is expected to be most deeply eroded.

8. A method of forming a physical vapor deposition target/backing plate construction, comprising:
providing a physical vapor deposition target, the target having a pair of opposing primary surfaces, one of the primary surfaces being a sputtering surface and the other of the primary surfaces being a bonding surface;
providing a backing plate having a bonding surface and a back surface in opposing relation to the bonding surface;
forming at least one hole extending into the backing plate through the backing plate bonding surface;
providing the target bonding surface proximate the backing plate bonding surface and bonding the target to the backing plate;
sputter-depositing material from the target onto a substrate; and
after the bonding and before the sputter-depositing, utilizing the hole to estimate a thickness of the target by ascertaining a time delay between ultrasound reflections from a surface of the hole and ultrasound reflections from one or more of the target primary surfaces, backing plate bonding surface and backing plate back surface.

9. The method of claim 8 wherein the target and backing plate are approximately the same in composition relative to one another.

10. The method of claim 8 wherein the bonding of the target to the backing plate comprises bonding the target to be physically against the backing plate.

11. The method of claim 8 wherein the target and backing plate are approximately the same in acoustic impedance relative to one another.

12. The method of claim 8 wherein the utilization of the hole to estimate the thickness of the target comprises ascertaining a time delay between ultrasound reflections from a surface of the hole and ultrasound reflections from the sputtering surface of the target.

13. The method of claim 8 further comprising, prior to the bonding, at least partially filling the hole with a material; and wherein the utilization of the hole to estimate the thickness of the target comprises ascertaining a time delay between ultrasound reflections from a surface of the material in the hole and ultrasound reflections from the sputtering surface of the target.

14. The method of claim 8 wherein:
multiple holes are formed to extend through the backing plate bonding surface and into the backing plate;
the multiple holes are utilized to estimate the thickness of the target and the uniformity of the target thickness.
